(19) United States
(12) Patent Application Publication
(10) Pub. No.: US 2023/0105004 A1
(43) Pub. Date: Apr. 6, 2023

(54) PROCESSING APPARATUS USING LASER, METHOD OF PROCESSING A SUBSTRATE USING LASER AND METHOD OF MANUFACTURING SEMICONDUCTOR DEVICE

(71) Applicant: Kioxia Corporation, Tokyo (JP)

(72) Inventors: Takuro OKUBO, Yokkaichi (JP); Hidekazu HAYASHI, Yokkaichi (JP)

(73) Assignee: Kioxia Corporation, Tokyo (JP)

(21) Appl. No.: 17/653,290

(22) Filed: Mar. 3, 2022

(30) Foreign Application Priority Data
Sep. 17, 2021 (JP) 2021-152673

(51) Int. Cl. H01L 21/268; B23K 26/08; B23K 26/067; B23K 26/0622; B23K 26/073

(52) U.S. Cl. CPC H01L 21/268; B23K 26/073; B23K 26/0622; B23K 26/0676; B23K 26/0823; B23K 2101/40

(57) ABSTRACT

A processing apparatus using laser according to an embodiment includes a stage configured to hold a plurality of substrates on concentric circles and rotates around a center of the concentric circles, and a laser irradiation apparatus capable of moving in a radial direction of the concentric circles, the laser irradiation apparatus including a control unit configured to control an output of an infrared pulsed laser so that a plurality of laser spots adjacent to each other are separated from each other.

### CROSS REFERENCE TO RELATED APPLICATION(S)

This application is based upon and claims the benefit of priority from the prior Japanese Patent Application JP2021-152673, filed on Sep. 17, 2021, the entire contents of which are incorporated herein by reference.

### FIELD

Embodiment described herein relate generally to a processing apparatus using laser, a method of processing a substrate using laser, and a method of manufacturing a semiconductor device.

### BACKGROUND

A NAND flash memory is known as a semiconductor device. The NAND flash memory includes a memory cell array and its control circuit. As a method of manufacturing a semiconductor device, a method is known in which a memory cell array chip and a control circuit chip are formed on the separate substrates and then bonded to each other later. In this case, the substrate on which the memory cell array chip is formed can be reused by laser.

### BRIEF DESCRIPTION OF THE DRAWINGS

FIG. 1 is a diagram showing an entire configuration of a semiconductor device according to the present embodiment;

FIG. 2 is a cross-sectional view showing a configuration of a semiconductor device according to the present embodiment;

FIG. 3 is a diagram showing an entire configuration of a semiconductor device according to the present embodiment;

FIG. 4 is a top view showing a basic configuration of a processing apparatus using laser according to the present embodiment;

FIG. 5 is a side view showing a basic configuration of a processing apparatus using laser according to the present embodiment;

FIG. 6 is an enlarged top view showing a laser irradiation area of a semiconductor device 1 according to the present embodiment;

FIG. 7 is a top view showing a basic configuration of a processing apparatus using laser according to the present embodiment;

FIG. 8 is a side view showing a basic configuration of a processing apparatus using laser according to the present embodiment;

FIG. 9A is an enlarged top view showing a laser irradiation area of a semiconductor device 1 according to the present embodiment; and

FIG. 9B is an enlarged top view showing a laser irradiation area of a semiconductor device 1 according to the present embodiment.

### DETAILED DESCRIPTION

Hereinafter, a processing apparatus using laser and a method of processing a substrate using laser according to the present embodiment will be described in detail with reference to drawings. In the following description, elements having substantially the same functions and configurations are denoted by the same symbols or with the same symbols followed by the addition of an alphabet and will be described in duplicate only when necessary. Each of the embodiments described below exemplifies an apparatus and a method for embodying a technical idea of this embodiment. Various changes may be made in the embodiment without departing from the gist of the invention. These embodiments and variations thereof are included in the scope of the invention described in the claims and the equivalents.

For the sake of clarity of description, although the drawings may be schematically represented with respect to widths, thicknesses, shapes, and the like of the respective portions compared with actual embodiments, they are merely an example and do not limit the interpretation of the present invention. In this specification and each drawing, elements having the same functions as those described with reference to the preceding drawings are denoted by the same symbols, and a repetitive description thereof may be omitted.

In each embodiment, a direction from each substrate toward the memory cells or the control circuits is referred to as above. On the contrary, a direction from the memory cells or the control circuits to each substrate is referred to as below. As described above, for convenience of explanation, although the phrase “above” or “below” is used for explanation, for example, the substrate and the memory cell may be arranged so that the vertical relationship thereof is opposite to that shown in the drawing. In the following description, for example, the expression “the memory cell on the substrate” merely describes the vertical relationship between the substrate and the memory cell as described above, and other members may be arranged between the substrate and the memory cell.

The expression “α includes A, B, or C” in this specification does not exclude the case where α includes multiple combinations of A to C unless otherwise specified. Furthermore, this expression does not exclude the case where α includes other elements.

The following embodiments may be combined with each other as long as there is no technical contradiction.

The processing apparatus using laser according to the present embodiment includes a stage configured to hold a plurality of substrates on concentric circles and rotates around a center of the concentric circles, and a the laser irradiation apparatus capable of moving in a radial direction of the concentric circles, the laser irradiation apparatus including a control unit configured to control an output of an infrared pulsed laser so that a plurality of laser spots adjacent to each other are separated from each other.

### First Embodiment

### Semiconductor Device

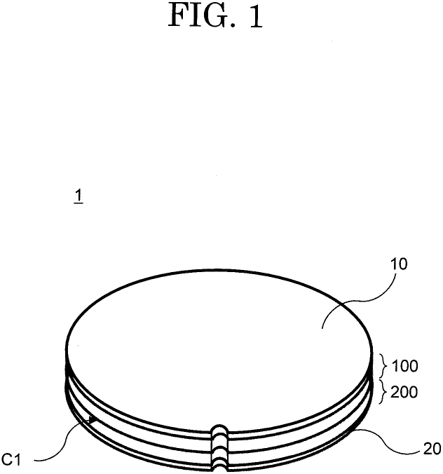

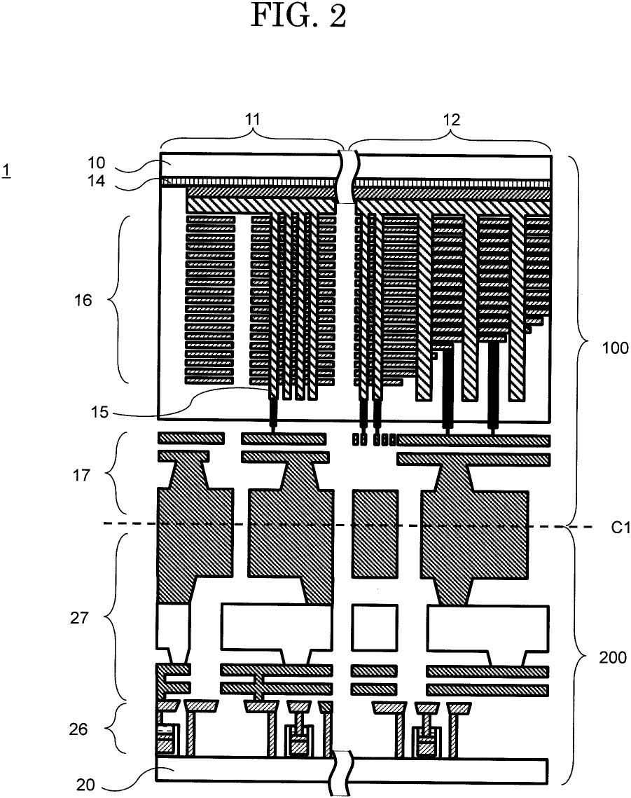

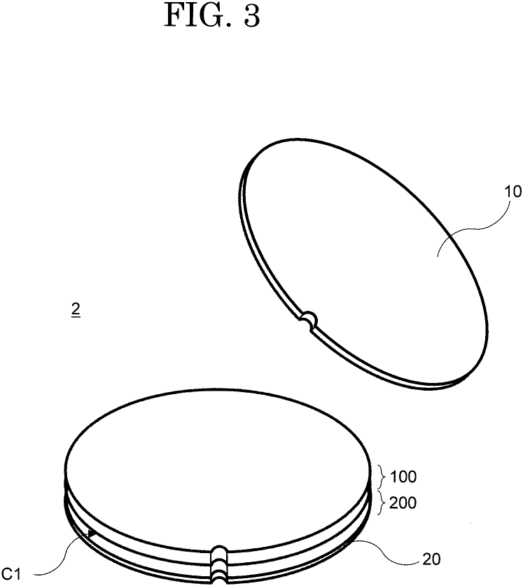

A configuration of a semiconductor device 1 according to the present embodiment will be described with reference to FIG. 1 to FIG. 3. FIG. 1 is a diagram showing an entire configuration of the semiconductor device 1. FIG. 2 is a cross-sectional view showing a basic configuration of the semiconductor device 1. FIG. 3 is a diagram showing an entire configuration of a semiconductor device 2. As shown in FIG. 1, the semiconductor device 1 includes a memory cell array chip 100 as a first circuit layer and a control circuit (CMOS circuit) chip 200 as a second circuit layer. Therefore, semiconductor device 1 may be referred to as bonded substrate 1. The memory cell array chip 100 and the control circuit chip 200 are connected by a connecting surface C1. The first circuit layer and the second circuit layer are not particularly limited.

### Structure of the Memory Cell Array Chip

As shown in FIG. 2, the memory cell array chip 100 includes a substrate 10, a laser absorption layer 14, a plurality of electrode layers 16, a plurality of semiconductor pillars 15, and a memory-side wiring layer 17. The plurality of electrode layers 16 is alternately stacked with a plurality of insulating layers on the substrate 10 via the laser absorption layer 14. Each of the semiconductor pillars 15 is arranged to penetrate the plurality of stacked electrode layers 16 in the direction perpendicular to the substrate 10. Each of the semiconductor pillars 15 is combined with the plurality of electrode layers 16 via the insulating layer to function as a plurality of transistors including memory cells. That is, in a memory cell array area 11, the plurality of transistors including memory cells is three-dimensionally arranged. The semiconductor pillar 15 is electrically connected to a source line at one end (the substrate 10 side) and to the memory-side wiring layer 17 at the other end (opposite to the substrate 10 side). A connecting terminal for connecting with the control circuit chip 200 is arranged on the connecting surface C1 opposite to the substrate 10 of the memory-side wiring layer 17.

A drawing area 12 (upper right portion in FIG. 2) is arranged on the substrate 10 along with the memory cell array area 11. In the drawing area 12, terminal portions of the plurality of electrode layers 16 are pulled out in a staircase pattern, respectively. Each terminal portion is connected to wirings arranged in the vertical direction through a contact hole opened in the insulating film. These wirings arranged in the vertical direction is electrically connected to the memory-side wiring layer 17 and is connected to the control circuit chip 200 via the connecting terminal.

The substrate 10 may be a semiconductor wafer such as a silicone substrate, or a glass substrate. The laser absorption layer 14 is arranged between the substrate 10 and the plurality of electrode layers 16. As shown in FIG. 3, the substrate 10 and the laser absorption layer 14 of the semiconductor device 1 according to the present embodiment are finally removed from the semiconductor device 1 by irradiating the laser absorption layer 14 with a laser in a manufacturing process of the semiconductor device. The laser absorption layer 14 is preferably, for example, a silicon oxide film. The semiconductor device 2 may be a semiconductor chip by individualized after removing the substrate 10 and the laser absorption layer 14. The substrate 10 peeled off by a laser processing may be reused.

### Structure of the Control Circuit Tip

As shown in FIG. 2, the control circuit chip 200 includes a substrate 20, a plurality of transistors 26 constituting a control circuit, and a circuit-side wiring layer 27. The plurality of transistors 26 is formed on the substrate 20 and electrically connected to the circuit-side wiring layer 27 on the opposite side of the substrate 20. A connecting terminal for connecting to the memory cell array chip 100 is arranged on the connecting surface C1 of the circuit-side wiring layer 27 opposite to the substrate 20. The substrate 20 may be a semiconductor wafer such as a silicon substrate.

### Processing Apparatus Using Laser

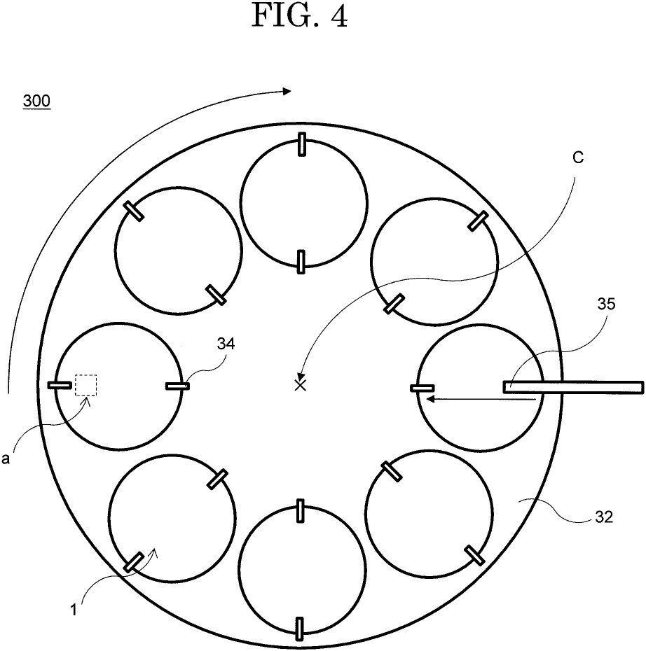

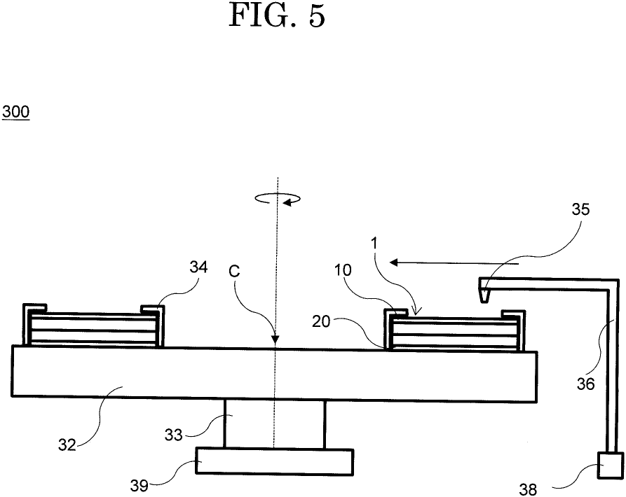

A processing apparatus using laser 300 according to the present embodiment will be described with reference to FIG. 4 and FIG. 5.

FIG. 4 is a top view showing a basic configuration of a processing apparatus using laser. FIG. 5 is a side view showing a basic configuration of a processing apparatus using laser. As shown in FIG. 4 and FIG. 5, the processing apparatus using laser 300 includes a stage 32 and a laser irradiation apparatus 35.

The stage 32 is circular and configured to hold a plurality of semiconductor devices (bonded substrates) 1 on concentric circles. In FIG. 4, the stage 32 holds eight semiconductor devices (bonded substrates) 1 on one circumference. However, the number of semiconductor devices (bonded substrates) 1 is not particularly limited and may be arranged on the circumferences of the different concentric circles. The semiconductor device 1 is preferably arranged separated from a center C of the concentric circles. The plurality of semiconductor devices (bonded substrates) 1 is arranged in a direction with the substrate 20 in the downward (stage 32 side) and the substrate 10 in the upward (opposite to substrate 32).

The stage 32 includes a rotating mechanism 33 and a control unit 39. The stage 32 rotates around a vertical axis including the center C of the concentric circles by the rotating mechanism 33. In FIG. 4, although a direction in which the stage 32 rotates clockwise (arrow) is shown, the stage 32 may rotate counterclockwise. As the stage 32 rotates, the semiconductor device 1 held by the stage 32 rotates around the center C with the circumference as an orbit. The rotational operation and rotational speed of the stage 32 driven by the rotational mechanism 33 are controlled by the control unit 39.

The stage 32 may include a holding mechanism 34. The holding mechanism 34 can hold the substrate 10, which is peeled from the semiconductor device 1 by the laser processing, on the stage 32. In FIG. 4, two holding mechanisms 34 were arranged per one semiconductor device 1. The holding mechanisms 34 were arranged at an end portion of the semiconductor device 1. However, the number and location of the holding mechanisms 34 per one semiconductor device 1 are not particularly limited. It is sufficient that the holding mechanism 34 does not interfere with the laser processing and can recover the peeled substrate 10. The substrate 10 collected without damage by the holding mechanism 34 can be reused.

The laser irradiation apparatus 35 is arranged above the stage 32. The laser irradiation apparatus 35 irradiates the laser absorption layer 14 of the semiconductor device 1 with a laser. The laser irradiation apparatus 35 irradiates a high-frequency pulsed laser that is oscillated from a laser oscillator (not shown). The laser is transparent to the substrate 10. Therefore, by irradiating the laser from the substrate 10 side of the semiconductor device 1, it is possible to focus and irradiate on the laser absorption layer 14 located below the substrate 10. The laser is preferably, for example, an infrared pulsed laser, and preferably, a carbon dioxide gas laser (CO₂ laser). Laser irradiation causes ablation of the laser absorption layer 14.

The laser irradiation apparatus 35 includes a moving mechanism 36 and a control unit 38. The laser irradiation apparatus 35 moves in the radial direction above the stage 32 by the moving mechanism 36. In FIG. 4 and FIG. 5, although a direction in which the laser irradiation apparatus 35 moves toward the center C from the end portion of the stage 32 is shown, the laser irradiation apparatus 35 may move toward the end portion from the center C of the stage 32. The laser irradiation apparatus 35 can move at least from end to end (range of the diameter) of the semiconductor device 1. As the laser irradiation apparatus 35 moves while the stage 32 rotates, the laser irradiation apparatus 35 irradiates the stage 32 with a laser along a spiral orbit. That is, the laser irradiation apparatus 35 irradiates the semiconductor device 1 arranged on the stage 32 with a laser along a striped orbit in which arcs of concentric circles are lined up. Since the semiconductor device 1 is sufficiently far from the center C of the stage 32, the orbit of the laser irradiated to the semiconductor device 1 is a striped pattern with almost straight lines. The moving operation and moving velocity of the laser irradiation apparatus 35 driven by the moving mechanism 36 and the laser output of the laser irradiation apparatus 35 are controlled by the control unit 38.

### Method of Processing a Substrate Using Laser

A method of laser irradiation and lift-off for removing the substrate 10 and the laser absorption layer 14 from the semiconductor device 1 using the processing apparatus using laser 300 according to the present embodiment will be described. The semiconductor device of the embodiment is manufactured using a method of laser irradiation and lift-off described below.

As shown in FIG. 4 and FIG. 5, the plurality of semiconductor devices 1 is arranged on the stage 32 with the substrate 20 in the downward (stage 32 side) and the substrate 10 in the upward (opposite to the substrate 32 side). By moving the laser irradiation apparatus 35 while rotating the stage 32, the laser irradiation apparatus 35 irradiates the stage 32 with a laser along a spiral orbit. The laser is focused and irradiated on the laser absorption layer 14 of the semiconductor device 1. The laser irradiation apparatus 35 moves at least from end to end (range of the diameter) of the semiconductor device 1.

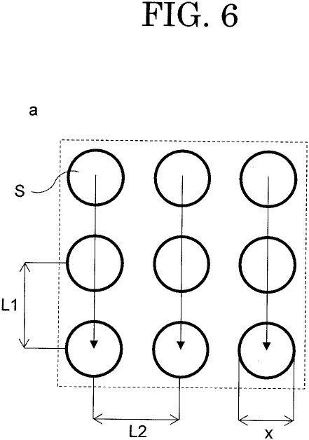

FIG. 6 is an enlarged top view showing a laser irradiation area of the semiconductor device 1. FIG. 6 is an enlarged top view at the top surface of the laser absorption layer 14 in FIG. 2 (area a in FIG. 4). As the stage 32 rotates, a laser spot S which is continuously irradiated moves in the direction opposite to the rotation direction of the stage 32 (arrow). That is, the two laser spots S which are continuously irradiated are adjacent to the rotational direction of the stage 32. An interval L1 between the two laser spots S, which are continuously irradiated, is a linear velocity / frequency of the pulsed laser. The interval L1 between the two laser spots S indicates a distance between the centers of the two laser spots S. The linear velocity of the pulsed laser is the moving velocity of the stage 32 (rotational speed) at the position of the laser irradiation apparatus 35 and controlled by the control unit 39. The position of the laser irradiation apparatus 35 and the frequency of the pulsed laser are controlled by the control unit 38.

In this embodiment, the interval L1 between the two laser spots S, which are continuously irradiated, is larger than a diameter x of the laser spot S (L1>x). That is, the two laser spots S adjacent to the rotational direction of the stage 32 are separated (L1-x). If the interval L1 between the two laser spots S is smaller than the diameter x of the laser spot S, the laser spot S may become dense and the substrate 10 may be damaged. The diameter x of the laser spot S indicates the full width at half maximum of the laser spot S on the top surface of the laser absorption layer 14. The diameter x of the laser spot is controlled by the control unit 38.

The interval L1 of all the laser spots S is preferably substantially the same. Therefore, the closer the position of the laser irradiation apparatus 35 to the center C, the rotational speed of the stage 32 is preferably increased. The closer the position of the laser irradiation apparatus 35 to the center C, the frequency of the pulsed laser is preferably reduced (increase the period of the pulse).

While the stage 32 rotates approximately once, the laser irradiation apparatus 35 moves toward the center C. That is, the lap-delayed laser spot S is adjacent to the previous laser spot S in the radial direction of the stage 32. An interval L2 between the two laser spots S adjacent to a moving direction of the laser irradiation apparatus 35 is a moving distance of the laser irradiation apparatus 35 while the stage 32 rotates once. The interval L2 between the two laser spots S indicates a distance between the centers of the two laser spots S. The moving distance of the laser irradiation apparatus 35 while the stage 32 rotates once is controlled by the control unit 38 according to the moving velocity of the laser irradiation apparatus 35.

In this embodiment, the interval L2 between the two laser spots S adjacent to the moving direction of the laser irradiation apparatus 35 is larger than the diameter x of the laser spot S (L2>x). That is, the two laser spots S adjacent to the radial direction of the stage 32 are separated (L2-x). If the interval L2 between the two laser spots S is smaller than the diameter x of the laser spot S, the laser spot S may become dense and the substrate 10 may be damaged.

The interval L2 of all the laser spots S is preferably substantially the same. Therefore, the moving velocity of the laser irradiation apparatus 35 is preferably constant. However, it is not limited thereto, in the case where the rotational speed of the stage 32 is increased to make the interval L1 between the laser spots S constant, the moving velocity of the laser irradiation apparatus 35 may be increased.

In the present embodiment, the interval L1 between the two laser spots S, which are continuously irradiated, and the interval L2 between the two laser spots S adjacent to the moving direction of the laser irradiation apparatus 35 are preferably substantially the same. That is, the intervals L1 and L2 between the laser spots S are preferably all equidistant.

In the method of laser irradiation and lift-off according to the present embodiment, the intervals L1 and L2 between the laser spots S and the diameter x of the laser spot can be appropriately adjusted by controlling the rotational speed of the stage 32, the moving velocity of the laser irradiation apparatus 35, and the laser output (the frequency of the pulsed laser, the diameter of the laser spot) of the laser irradiation apparatus 35 of the processing apparatus using laser 300 by the control units 38 and 39. By controlling the intervals L1, L2 between the laser spots S and the diameter x of the laser spot to the extent described above, the plurality of semiconductor devices 1 can be efficiently and uniformly irradiated with a laser, and a bonding force of the laser absorption layer 14 can be reduced to separate the substrate 10 from the semiconductor device 1. Therefore, the method of processing a substrate using laser according to the present embodiment can improve the manufacturing efficiency of the semiconductor device 2 and a reuse efficiency of the substrate 10.

In the present embodiment, a configuration that the two control units 38, 39 control the rotation speed of the stage 32, the movement speed of the laser irradiation apparatus 35, and the laser output (the frequency of the pulsed laser, the diameter of the laser spot) of the laser irradiation apparatus 35 of the processing apparatus using laser 300, respectively, is shown. However, it is not limited thereto, the rotational speed of the stage 32, the moving velocity of the laser irradiation apparatus 35, and the laser output (the frequency of the pulsed laser, the diameter of the laser spot) of the laser irradiation apparatus 35 of the processing apparatus using laser 300 may be integrated and controlled by one control unit.

The configuration that the laser irradiation apparatus 35 oscillates one laser beam has shown. However, it is not limited thereto, the laser irradiation apparatus 35 may be configured to oscillate a plurality of laser beams. In this case, the plurality of laser beams may be arranged separated L2 in the radial direction of the stage 32, and the plurality of laser beams may be arranged with a distance of the radius of the semiconductor device 1 in the radial direction of the stage 32. By controlling the intervals L1, L2 between the laser spot S to the range described above, to the laser can be irradiated more efficiently.

### Second Embodiment

The configuration of a processing apparatus using laser 300A according to the present embodiment is the same as the configuration of the processing apparatus using laser 300 according to the first embodiment except that it is provided with two laser irradiation apparatuses 35a and 35b. Descriptions that are the same as those of the first embodiment are omitted, and portions different from the configuration of the processing apparatus using laser according to the first embodiment will be described.

### Processing Apparatus Using Laser

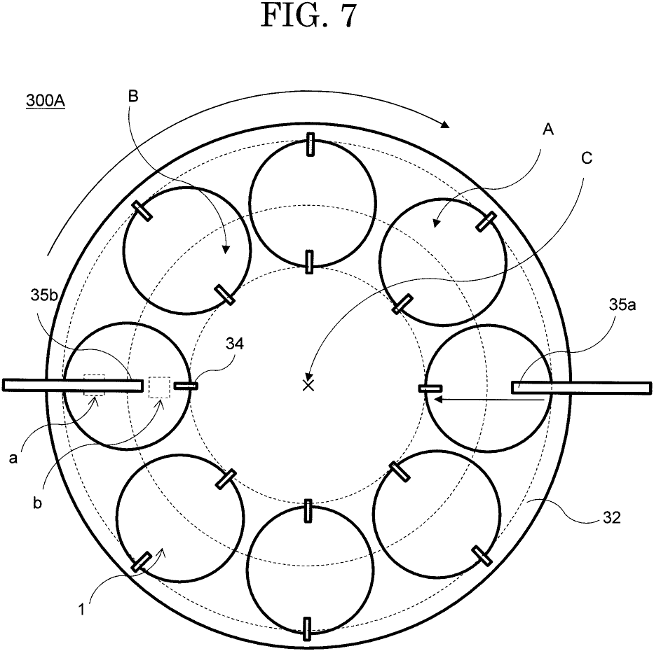

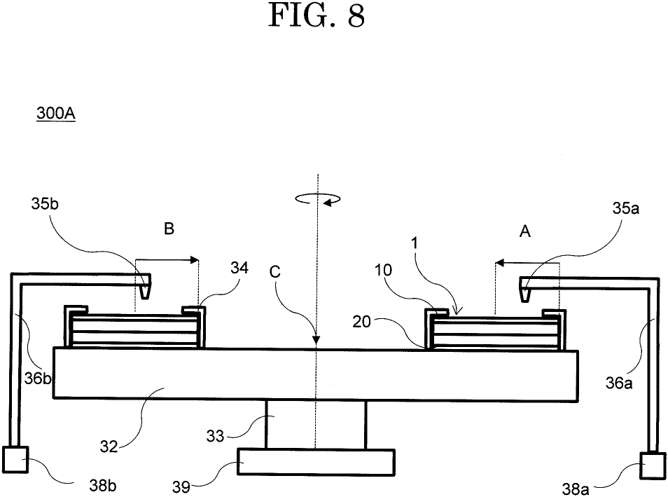

The processing apparatus using laser 300A according to the present embodiment will be described with reference to FIG. 7 and FIG. 8.

FIG. 7 is a top view showing a basic configuration of a processing apparatus using laser. FIG. 8 is a side view showing a basic configuration of a processing apparatus using laser. As shown in FIG. 7 and FIG. 8, the processing apparatus using laser 300A includes the stage 32 and the two laser irradiation apparatuses 35a, 35b. In the present embodiment, although a configuration including the two the laser irradiation apparatuses 35a and 35b will be described, the number of the laser irradiation apparatuses 35 may be two or more.

The laser irradiation apparatuses 35a, 35b include a moving mechanism 36a, 26b, and control units 38a, 38b, respectively. The laser irradiation apparatuses 35a, 35b move independently in the radial direction above the stage 32 by each of the moving mechanism 36a, 36b. In FIG. 7 and FIG. 8, the laser irradiation apparatus 35a moves within an area A in the radial direction, and the laser irradiation apparatus 35b moves within an area B in the radial direction. Although the direction (arrow) that the laser irradiation apparatuses 35a, 35b move toward the center C side from the end side of the stage 32 has shown, it may be moved toward the end side from the center C side of the stage 32. The two laser irradiation apparatuses 35a, 35b can move at least from end to end (range of the diameter) of the semiconductor device 1. As the laser irradiation apparatuses 35a and 35b move within their respective areas while the stage 32 rotates, the laser irradiation apparatuses 35a and 35b irradiate the stage 32 with a laser along two spiral orbits. That is, the laser irradiation apparatus 35a irradiates the laser along the spiral orbit in the area A. The laser irradiation apparatus 35b irradiates the laser along the spiral orbit in the area B. The laser irradiation apparatuses 35a and 35b irradiate the semiconductor device 1 arranged on the stage 32 with a laser along a striped orbit in which arcs of concentric circles are lined up. Although the laser irradiation apparatuses 35a, 35b are arranged at a position facing each other across the center C of the stage 32, the positions of the laser irradiation apparatus 35a, 35b are not particularly limited. The positions of the laser irradiation apparatuses 35a, 35b need not be adjacent to the circumference of one concentric circle and need not be adjacent to the radial direction of the stage 32.

### Method of Processing a Substrate Using Laser Lift-Off

A method of laser irradiation and lift-off for removing the substrate 10 and the laser absorption layer 14 from the semiconductor device 1 by using the processing apparatus using laser 300A according to the present embodiment will be described.

As shown in FIG. 7 and FIG. 8, the plurality of semiconductor devices 1 is arranged on the stage 32 in a direction with the substrate 20 in the downward (stage 32 side) and the substrate 10 in the upward (opposite to the substrate 32 side). By moving the laser irradiation apparatuses 35a and 35b while rotating the stage 32, the laser irradiation apparatuses 35a and 35b irradiate the stage 32 with a laser along two spiral orbits. The laser is focused and irradiated on the laser absorption layer 14 of the semiconductor device 1. The laser irradiation apparatus 35a moves within the area A (the area outside the center of the semiconductor device 1) of the semiconductor device 1. The laser irradiation apparatus 35b moves within the area B (the area inside the center of the semiconductor device 1) of the semiconductor device 1.

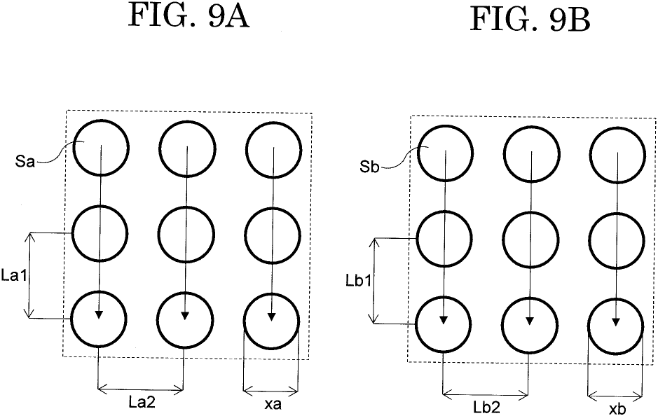

FIG. 9A and FIG. 9B are enlarged top views showing a laser irradiation area of the semiconductor device 1. FIG. 9A is an enlarged top view in an area a in FIG. 7. FIG. 9B is an enlarged top view in an area b in FIG. 7. As the stage 32 rotates, two laser spots Sa, Sb, which are continuously irradiated, move in the direction (arrow) opposite to the rotation direction of the stage 32, respectively.

In the method of laser irradiation and lift-off according to the present embodiment, by controlling the rotational speed of the stage 32, the moving velocity of the laser irradiation apparatus 35a, and the laser output (the frequency of the pulsed laser, the diameter of the laser spot) of the laser irradiation apparatus 35a of the processing apparatus using laser 300A by the control units 38a, 39, a diameter xa of the laser spot in the area a, an interval La1 between the two laser spots Sa which are continuously irradiated, and an interval La2 of the two laser spots Sa adjacent to the moving direction of the laser irradiation apparatus 35a can be appropriately adjusted as in the first embodiment. By controlling the rotational speed of the stage 32, the moving velocity of the laser irradiation apparatus 35b, and the laser output (the frequency of the pulsed laser, the diameter of the laser spot) of the laser irradiation apparatus 35b of the processing apparatus using laser 300A by the control units 38b, 39, a diameter xb of the laser spot in the area b, an interval Lb1 between the two laser spots Sb which are continuously irradiated, and an interval Lb2 between the two laser spots Sb adjacent to the moving direction of the laser irradiation apparatus 35b can be appropriately adjusted as in the first embodiment. Therefore, repeated descriptions will be omitted.

In the present embodiment, the diameter xa of the laser spot in the area a and the diameter xb of the laser spot in the area b are preferably substantially the same. The diameters xa, xb of the laser spots are controlled by the control units 38a, 38b, respectively.

The interval La1 between the two laser spots Sa, which are continuously irradiated in the area a, and the interval Lb1 between the two laser spots Sb, which are continuously irradiated in the area b, are preferably substantially the same. Therefore, the laser irradiation apparatus 35b having a small distance from the center C preferably has a smaller frequency of the pulsed laser (increasing the period of the pulse) than the laser irradiation apparatus 35a having a large distance from the center C. The frequencies of the pulsed lasers of the laser irradiation apparatuses 35a and 35b are controlled by the control units 38a and 38b, respectively.

The interval La2 between the two laser spots Sa adjacent to the moving direction of the laser irradiation apparatus 35a in the area a, and the interval Lb2 between the two laser spots Sb adjacent to the moving direction of the laser irradiation apparatus 35b in the area b are preferably substantially the same. Therefore, the moving velocities of the laser irradiation apparatuses 35a and 35b are preferably substantially the same.

In the present embodiment, the intervals La1, Lb1 of the two laser spots Sa, Sb, which are continuously irradiated, and the intervals La2, Lb2 of the two laser spots Sa, Sb adjacent to the moving direction of 35b, 35b are preferably substantially the same. That is, intervals La1, Lb1, La2, Lb2 between the laser spots Sa and Sb are preferably all equidistant.

By controlling the intervals La1, Lb1, La2, Lb2 of the laser spots Sa, Sb, and the diameters xa, xb of the laser spots to the range described above, the plurality of semiconductor devices (bonded substrates) 1 can be efficiently and uniformly irradiated with a laser, and the bonding force of the laser absorption layer 14 can be reduced to separate the substrate 10 from the semiconductor device 1. Therefore, the method of laser lift-off according to the present embodiment can improve the manufacturing efficiency of the semiconductor device 2 and the reuse efficiency of the substrate 10.

In the present embodiment, the configuration that the three control units 38a, 38b, and 39 control the rotational speed of the stage 32, the laser irradiation apparatus 35a, the moving velocity of 35b, and the laser output (the frequency of the pulsed laser, the diameter of the laser spot) of the laser irradiation apparatuses 35a, 35b of the processing apparatus using laser 300A, respectively, is shown. However, it is not limited thereto, the rotational speed of the stage 32, the moving velocity of the laser irradiation apparatuses 35a and 35b, and the laser output (the frequency of the pulsed laser, the diameter of the laser spot) of the laser irradiation apparatuses 35a and 35b of the processing apparatus using laser 300A may be integrated and controlled by one control unit.

The configuration in which the laser irradiation apparatuses 35a, 35b move in different areas A, B has shown. However, it is not limited thereto, and the laser irradiating apparatuses 35a and 35b may be configured to move in the same area as in the first embodiment. In this case, the positions of the laser irradiation apparatus 35a and 35b may be offset L2 in the radial direction of the stage 32, the moving velocity of the laser irradiation apparatus 35a and 35b may be twice, respectively. With this configuration, the orbits that the laser irradiation apparatuses 35a and 35b irradiate the laser are such that one spiral is nested between the other spirals, and the two orbits are uniformly irradiated with the laser without intersecting.

In the first and second embodiment, the semiconductor device 1 is shown as an object to be processed, but is not limited thereto. For example, any substrate having a laser absorption layer may be used as an object to be processed.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A processing apparatus using laser comprising:
a stage configured to hold a plurality of substrates on concentric circles and rotates around a center of the concentric circles; and
a laser irradiation apparatus capable of moving in a radial direction of the concentric circles, the laser irradiation apparatus including a control unit configured to control an output of an infrared pulsed laser so that a plurality of laser spots adjacent to each other are separated from each other.

2. The processing apparatus using laser according to claim 1, wherein the control unit controls so as to satisfy x<L1 when a diameter of the plurality of laser spots is x and a distance between the plurality of laser spots adjacent to each other in a rotation direction of the stage is L1.

3. The processing apparatus using laser according to claim 2, wherein the L1 is a linear velocity / frequency of the infrared pulsed laser.

4. The processing apparatus using laser according to claim 2, wherein the control unit controls so as to satisfy x<L2 when a distance between the plurality of laser spots adjacent to each other in a moving direction of the laser irradiation apparatus is L2.

5. The processing apparatus using laser according to claim 1, wherein the control unit controls a diameter and frequency of the plurality of laser spots.

6. The processing apparatus using laser according to claim 1, wherein the infrared pulsed laser includes a carbon dioxide gas laser.

7. The processing apparatus using laser according to claim 1, further comprising another laser irradiation apparatus capable of moving in a radial direction of the concentric circles.

8. The processing apparatus using laser according to claim 7, wherein the another laser irradiation apparatus outputs the infrared pulsed laser having a frequency different from that of the laser irradiation apparatus.

9. A method of processing a substrate using laser comprising:
arranging a plurality of substrates on concentric circles of a stage, each of the plurality of bonded substrates includes a laser absorption layer;
rotating the stage around a center of the concentric circles; and
moving a laser irradiation apparatus in a radial direction of the concentric circles, the laser irradiation apparatus irradiates the laser absorption layer with an infrared pulsed laser.

10. The method of processing the substrate using laser according to claim 9, wherein the laser irradiation apparatus controls an output of the infrared pulsed laser so that a plurality of laser spots adjacent to each other are separated from each other.

11. The method of processing the substrate using laser according to claim 10, wherein the laser irradiation apparatus controls so as to satisfy x<L1 when a diameter of the plurality of laser spots is x and a distance between the plurality of laser spots adjacent to each other in a rotation direction of the stage is L1.

12. The method of processing the substrate using laser according to claim 11, wherein the L1 is a linear velocity / frequency of the infrared pulsed laser.

13. The method of processing the substrate using laser according to claim 11, wherein the control unit controls so as to satisfy x<L2 when a distance between the plurality of laser spots adjacent to each other in a moving direction of the laser irradiation apparatus is L2.

14. The method of processing the substrate using laser according to claim 11, wherein the infrared pulsed laser includes a carbon dioxide gas laser.

15. A method of manufacturing a semiconductor device comprising:
arranging a plurality of bonded substrates on concentric circles of a stage, each of the plurality of bonded substrates includes a first substrate and a second substrate bonded via a laser absorption layer;
rotating the stage around a center of the concentric circles;
moving a laser irradiation apparatus in a radial direction of the concentric circles, the laser irradiation apparatus irradiates the laser absorption layer with an infrared pulsed laser; and
removing the second substrate from the first substrate.

16. The method of manufacturing a semiconductor device according to claim 15, wherein the laser absorption layer includes a silicon oxide film.

17. The method of manufacturing a semiconductor device according to claim 15, wherein each of the plurality of bonded substrates includes a CMOS circuit, a memory cell array, and the laser absorbing layer between the first substrate and the second substrate, and irradiates the infrared pulsed laser from the second substrate side.
